(19) United States
(12) Patent Application Publication
(10) Pub. No.: US 2009/0200938 A2
(43) Pub. Date: Aug. 13, 2009

(54) FLEXIBLE ORGANIC LIGHT EMITTING DEVICES

(75) Inventors: Furong ZHU, (SG); Kian ONG, (SG); Xiao HAO, (SG)

Correspondence Address: FINNEGAN, HENDERSON, FARABOW, GARRETT & DUNNER;LLP, 901 NEW YORK AVENUE, NW, WASHINGTON, DC, 20001-4413, UNITED STATES, 202-408-4000

(73) Assignee: AGENCY FOR SCIENCE, TECHNOLOGY AND RESEARCH, (SG)

(21) Appl. No.: 11/336,879

(22) Filed: Jan. 23, 2006

Related U.S. Application Data
(63) Continuation-in-part of application No. PCT/SG04/00025, filed on Jan. 28, 2004.

(51) Int. Cl. H01L 51/50; H05B 33/00

(52) U.S. Cl. 313/506; 313/511; 313/512; 313/113; 313/114; 428/917; 438/29; 257/98; 257/E51.021

(57) ABSTRACT

A flexible organic light emitting device and a method of fabricating the same. The device comprises a flexible substrate comprising a plastic material; an organic emissive layer formed on the substrate; and a barrier layer for inhibiting oxygen and moisture permeation into the emissive layer.

### FIELD OF THE INVENTION

The present invention generally relates to flexible organic light emitting devices, and to a method of fabricating a flexible organic light emitting device.

### BACKGROUND OF THE INVENTION

Organic light emitting devices (OLEDs) have recently attracted attention as display devices that can replace liquid crystal displays (LCDs) because OLEDs can produce high visibility by self-luminescence, thus, they do not require back-lighting, which are necessary for LCDs. A typical OLED is constructed by placing an organic light-emitting material between a cathode layer that can inject electrons and an anode layer that can inject holes. When a voltage of proper polarity is applied between the cathode and anode, holes injected from the anode and electrons injected from the cathode combine to release energy as light, thereby producing electroluminescence. Polymeric electroluminescent and phosphorescent materials have been used for OLEDs, which devices are referred to as PLEDs.

One conventional structure of OLED is a bottom-emitting structure, which includes an upper opaque electrode and a transparent lower electrode on a transparent substrate, whereby light can be emitted from the bottom of the structure. The OLED may also have a top-emitting structure (TOLED), which may be formed on either an opaque substrate or a transparent substrate and has a relatively transparent upper electrode so that light additionally or alternatively emit from the side of the upper electrode.

The demand for more user-friendly displays has increased efforts to produce OLED structures that are flexible, lighter, more cost-effective, and more environmentally friendly than those currently available. Flexible thin-film OLED displays can enable the production of a wide range of e.g. entertainment-related, wireless, wearable-computing, and network-enable devices:

To-date, efforts to fabricate flexible OLEDs have been focused on utilizing plastic substrates, in particular transparent flexible substrates for conventional bottom-emitting OLED structures. However, such plastic substrates do not provide sufficient protection of the electroluminescent polymeric or organic layers in the OLEDs, due to their non-negligible oxygen and moisture permeability.

Polymer-reinforced ultra thin glass sheets have also been suggested as an alternative substrate for flexible OLEDs. However, to-date, such glass sheets remain limited in terms of the degree of flexibility achievable.

A need therefore exist to provide a flexible substrate OLED structure that seeks to address at least one of the above-mentioned problems.

### SUMMARY OF THE INVENTION

In accordance with a first aspect of the present invention there is provided a flexible organic light emitting device comprising a flexible substrate comprising a plastic material; an organic emissive layer formed on the substrate; and a barrier layer for inhibiting oxygen and moisture permeation into the emissive layer.

The substrate may further comprise the barrier layer.

The substrate may comprise a plastic foil laminated to or coated with the barrier layer.

The substrate may comprise the barrier layer sandwiched between two plastic foils.

The plastic foil may comprise a PET foil.

The barrier layer may comprise a metallic layer.

The device may further comprise a first electrode layer.

The first electrode layer may comprise the barrier layer.

The first electrode layer may further comprise a transparent conductive layer.

The transparent conductive layer may comprise one or more transparent conducting oxides.

The first electrode layer may comprise a metallic or modified metallic electrode.

The device may further comprise an optical micro-cavity including the emissive layer.

The micro-cavity may further include a semitransparent second electrode layer formed on the organic emissive layer.

The micro-cavity further may include the barrier layer as a reflective element on an opposite side of the emissive layer compared to the second electrode layer.

An optical thickness of the micro-cavity may be chosen such that the device exhibits a pre-determined emission wavelength.

The device may be incorporated in one of a group consisting of a flexible display, a pre-formed curved display, and electroluminance based lighting devices.

In accordance with a second aspect of the present invention there is provided a method of fabricating a flexible organic light emitting device, the method comprising providing a flexible substrate comprising a plastic material; forming an organic emissive layer on the substrate; and providing a barrier layer for inhibiting oxygen and moisture permeation into the emissive layer.

The method may further comprise forming an optical micro-cavity including the emissive layer.

An optical thickness of the micro-cavity may be chosen such that the device exhibits a pre-determined emission wavelength.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic cross-sectional drawing of a TOLED structure according to a first example embodiment.

FIGS. 2a to c are atomic force microscopy (AFM) images illustrating surface roughness of a substrate at different fabrication stages.

FIG. 3 is a schematic cross-sectional drawing of a TOLED structure according to a second example embodiment.

FIGS. 4a and b are graphs showing a comparison of I-V and L-V characteristics respectively of example embodiments and a reference OLED structure.

FIG. 5 shows a graph of normalized electroluminance spectra for different example embodiments, and a non-cavity OLED structure.

FIGS. 6a to c are graphs showing a comparison of I-V and L-V, and luminous efficiency-voltage characteristics respectively of example embodiments and a reference OLED structure.

FIG. 7 shows a flow-chart 700 illustrating a method of fabricating a flexible organic light emitting device.

### DESCRIPTION OF THE PREFERRED EMBODIMENTS

The example embodiments described provide flexible substrate OLED structures which comprise a barrier against oxygen and moisture penetration into active layers of the OLED structure.

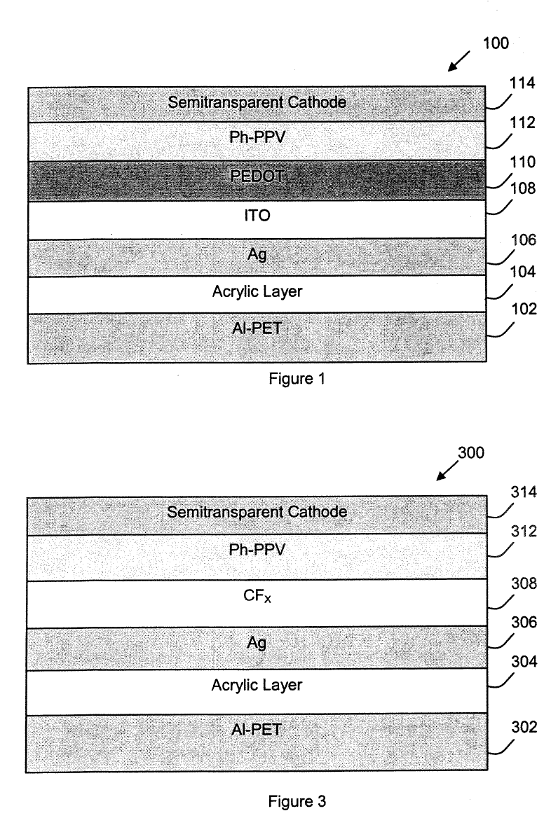

FIG. 1 shows a schematic cross-sectional drawing of a TOLED structure 100 according to a first embodiment. The OLED structure 100 comprises a flexible plastic-metal substrate in the form of an aluminum-laminated polyethylene terephthalate (Al-PET) foil 102. An acrylic layer 104 is formed on the Al-PET layer 102 for improvement of adhesion of a first electrode in the form of a silver (Ag) anode layer 106, as will be described in more detail below. In the example embodiment, the acrylic layer 104 is coated on the Al-PET foil 102 (about 0.1-mm thickness, 400 Gauge Mylar 453) utilizing an ultra violet (UV)—curable acrylic material. The acrylic material used for the acrylic layer 104 is SK 3200 (SONY Chemical), which is an UV-curable acrylic based lacquer. The thin layer 104 of acrylic material is deposited using a solution spin-coating method following a curing process. The thickness of the acrylic layer 104 is about 2-3 microns. The aluminum layer of the Al-PET layer 102 is located at the “bottom” of the OLED structure 100. However, it will be appreciated that the aluminum layer may be provided between the acrylic layer 104 and the Al-PET foil 102 in other embodiments.

The Ag anode 106 is deposited by thermal evaporation, to a thickness of about 200 nm, and is then overlaid on a transparent conductive layer in the form of an indium-tin-oxide (ITO) layer 108 of a thickness of about 130 nm by physical vacuum deposition techniques such as RF Magnetron sputtering.

The TOLED structure 100 further comprises a spin-coated PEDOT layer 110 as a hole transporting layer (HTL), and a spin-coated Ph-PPV layer 112 as an emissive layer. In the example embodiment, prior to the spin coating of the PEDOT layer 110, the ITO layer 108 was treated by oxygen plasma.

A semitransparent second electrode in the form of a cathode layer 114 is formed on the Ph-PPV layer 112, completing the TOLED structure 100. The semitransparent cathode layer 114 has a multilayer architecture in the example embodiment, consisting of organic and inorganic layers. The semitransparent cathode layer 114 is prepared using known thermal evaporation techniques, without incurring radiation damage to the underlying layers, in particular the underlying Ph-PPV layer 112.

In the example embodiment, the deposition of organic and cathode materials was controlled at a constant rate of about 1.0±0.2 Å/s, and the thickness of the organic and metal layers was estimated and controlled by the deposition time.

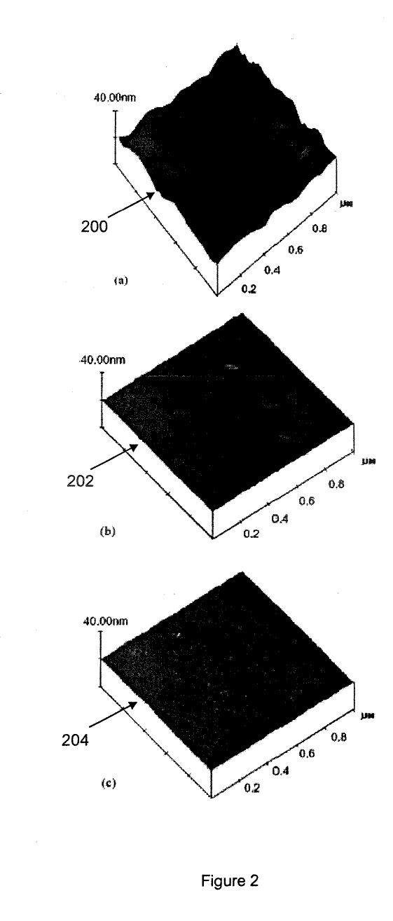

As mentioned above, an acrylic layer 104 is formed on the Al-PET layer 102 for improvement of adhesion of the Ag layer 106. FIGS. 2a to c show atomic force microscopy (AFM) images of a bare PET, PET with an acrylic layer, and an about 130 nm thick ITO film on an acyclic-layer-coated PET respectively.

The surface of the bare PET 200 has an RMS roughness of about 6.0±0.1 nm (FIG. 2a). On the other hand PET with an acrylic-layer 202 has a much lower RMS roughness of about 0.4±0.1 nm (FIG. 2b). Furthermore, from FIG. 2c it can be seen that the ITO-coated acrylic-layer PET foil 204 also has a very similar smooth surface with an RMS roughness of about 0.4±0.1 nm, which is found to be suitable for OLED fabrication. It was found that the presence of an acrylic-layer improves the adhesion between the anode contact and the substrate when subjected to bending as a function of number of cycles from flat to a fix radius of curvature of about 12.5 mm.

FIG. 3 shows a schematic cross-sectional drawing of a TOLED structure 300 according to a second example embodiment. The OLED structure 300 comprises a flexible plastic-metal substrate in the form of an aluminum-laminated polyethylene terephthalate (Al-PET) foil 302. An acrylic-layer 304 is formed on the Al-PET layer 302 for improvement of adhesion of a first electrode in the form of anode silver (Ag) layer 306. In the example embodiment, the acrylic-layer 304 is coated on the Al-PET foil 302 (0.1-mm thickness, 400 Gauge Mylar 453) utilizing an ultra violet (UV)—curable acrylic material. The acrylic layer 304 is made from SK 3200, with a thickness of about 2-3 microns. The acrylic-layer 304 is spin-coated on the Al-PET foil 302. The aluminum layer of the Al-PET layer 302 is located at the “bottom” of the OLED structure 300. However, it will be appreciated that the aluminum layer may be provided between the acrylic layer 104 and the Al-PET foil 302 in other embodiments.

The Ag anode 306 is deposited by thermal evaporation, to a thickness of about 200 nm, and is then modified with an about 0.3 nm thick fluorocarbon (CFₓ) layer 308, by plasma polymerization.

The TOLED structure 300 further comprises a spin-coated Ph-PPV layer 312 as an emissive layer. A semitransparent second electrode in the form of a cathode layer 314 is formed on the Ph-PPV layer 312, completing the TOLED structure 300. The semitransparent cathode layer 314 has a multilayer architecture in the example embodiment, consisting of organic and inorganic layers. The semitransparent cathode layer 314 is prepared using known thermal evaporation techniques, without incurring radiation damage to the underlying layers, in particular the underlying Ph-PPV layer 312.

In the example embodiment, the deposition of organic and cathode materials was controlled at a constant rate of about 1.0±0.2 Å/s, and the thickness of the organic and metal layers was estimated and controlled by the deposition time.

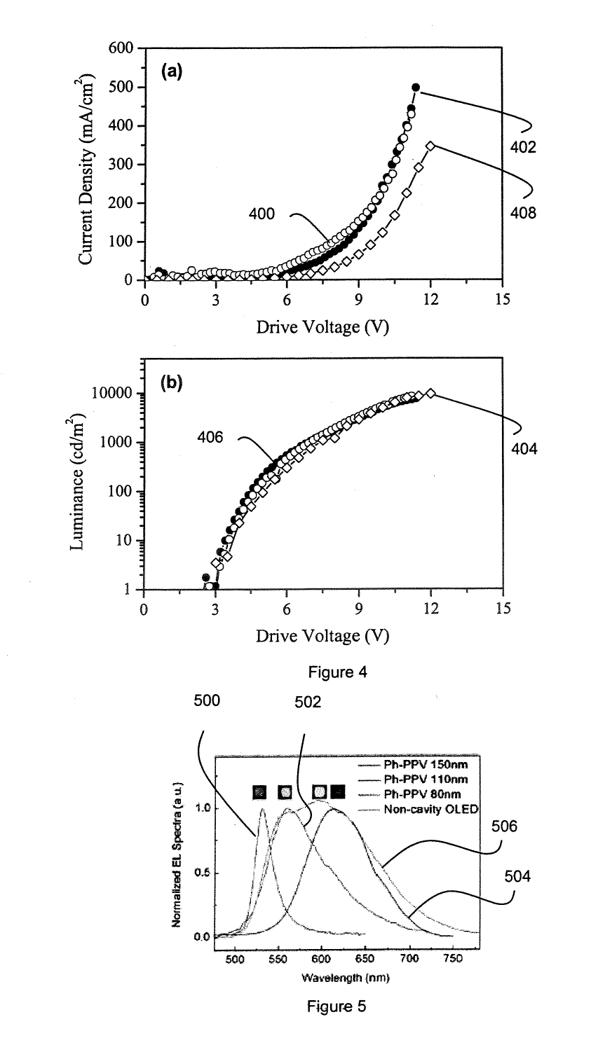

A comparison between I-V and L-V characteristics of the first and second embodiments, and a rigid reference OLED structure is shown in FIGS. 4a and b respectively. The reference OLED structure has a configuration of glass/Ag (about 200 nm)/ITO (about 130 nm)/PEDOT (80 nm)/Ph-PPV (about 80 nm)/semitransparent cathode. From FIG. 4a it can be seen that the first embodiment (curve 400) has an almost identical current density performance compared to the reference OLED structure (curve 402). Similarly, with reference to FIG. 4b, the first embodiment (curve 404) has an almost identical luminance characteristic as the reference OLED structure (curve 406). This shows that the first embodiment, which differs from the reference structure only in terms of having a flexible substrate structure as opposed to the rigid glass substrate of the reference structure, can provide a flexible substrate OLED structure without deterioration of the current density-voltage characteristics and luminance-voltage characteristics.

For the second embodiment (curve 408, FIG. 4a), a slightly higher operating voltage is required to achieve a similar current density, as compared to the first embodiment (curve 400) and the reference OLED structure (curve 402). This may be attributed to a thicker Ph-PPV layer of about 110 nm used in the second embodiment, but other results indicated that both Ag/ITO and Ag/CFₓ exhibit a similar hole injection behavior in OLEDs. From FIG. 4b it can be considered that devices with both architectures have comparable carrier injection properties, as both devices use the same polymeric light-emitting layer and the cathode structure.

In the following, experimental data concerning color tuning and efficiency enhancement will be described, for TOLED structures with a configuration Al-PET/Ag (about 200 nm)/CFₓ (about 0.3 nm)/Ph-PPV (about 80 to 150 nm)—semitransparent cathode, based on the second embodiment described above with reference to FIG. 3.

The emissive Ph-PPV layer sandwiched between the bilayer anode of Ag/CFₓ and the semitransparent cathode forms and optical micro-cavity. By varying the thickness of the Ph-PPV layer, and thus the optical micro-cavity dimensions, the emission color can be tuned.

FIG. 5 shows normalized electro luminance (EL) spectra for different Ph-PPV thicknesses, and for a non-cavity Ph-PPV OLED. A clear red shift in the electroluminance (EL) peak position from 530 to 610 nm can be observed with a Ph-PPV thickness varied from about 80 to about 150 nm, comparing curves 500, 502, and 504 respectively. The results shown in FIG. 5 demonstrate the optical micro-cavity effect achievable with TOLED structures according to example embodiments. It is noted that the full-width at half maximum (FWHM) of the EL peak for the non-cavity OLED structure (curve 506) was 137 nm, whereas the FWHM values obtained for the micro-cavity TOLEDs with emission layer thickness of about 80, about 110, and about 150 nm (curves 500, 502, 504) were 25, 77, and 120 nm respectively. Again, these observations are attributed to the optical micro-cavity effect.

The emission from a Fabry-Perot micro-cavity is determined by the resonance mode of the cavity, and the spectral position of the cavity mode can be determined by the optical thickness of the cavity,

$$L = k ( \frac{{λ}_{k}}{2} ) \qquad ( 1 )$$

where k=1, 2, 3 . . . is the mode index, L is the optical thickness of the cavity, and λₖ is the mode wavelength of the cavity.

The optical thickness of the cavity can be calculated, taking into account a substantial penetration depth into the semitransparent mirror, by

$$L = \frac{{λ}_{v}}{2} ( \frac{{n}_{eff}}{Δ n} ) + {\sum }_{i} {n}_{i} {d}_{i} + \vert \frac{{Φ}_{m}}{4 π} {λ}_{v} \vert \qquad ( 2 )$$

The first term is the effective penetration depth in the semitransparent mirror layer, λₖ is the vacuum wavelength, n_{eff} is the effective refractive index of the semitransparent mirror, Δn is the difference between the indexes of the materials of the semitransparent mirror layer, and nᵢ and dᵢ are the refractive index and the thickness respectively of the different layers within the microcavity, including the different organic and inorganic materials.

The last term in equation (2) is the optical thickness contributed by the phase shift at the interface of the metal layer and the Ph-PPV layer, and Øₘ is the phase shift at the interface, depending on the refractive indices of the metal and the Ph-PPV layer at the interfaces,

$${Φ}_{m} = arctan ( \frac{2 {n}_{m} {k}_{m}}{{n}_{s}^{2} - {n}_{m}^{2} - {k}_{m}^{2}} ) \qquad ( 3 )$$

where nₛ, is the refractive index of Ph-PPV in contact with the metal and nₘ, kₘ are the real and imaginary parts of the refractive index of the metal.

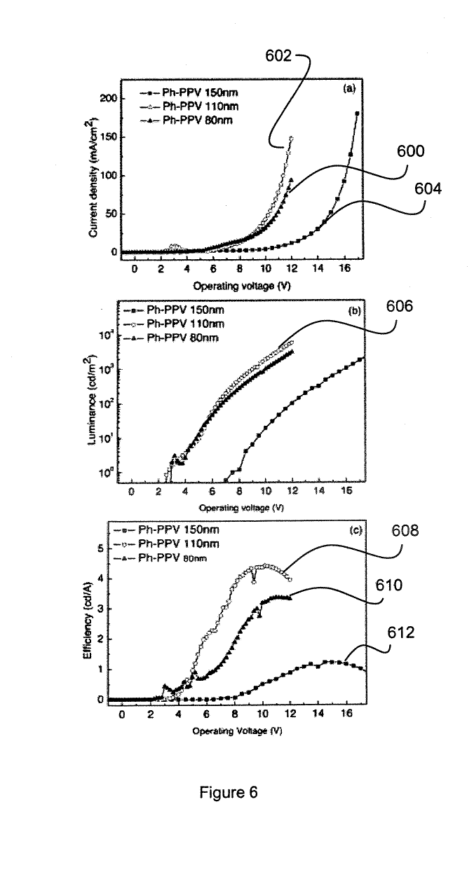

The I-V, L-V, and luminous efficiency-voltage characteristics of the TOLEDs with different Ph-PPV thickness are shown in FIG. 6a to c, respectively. The turn-on voltage for the TOLEDs with Ph-PPV thickness of about 80 and about 110 nm (curves 600, 602) in FIG. 6a is around 2.5V. The turn-on voltage is increased to about 7.5V for a Ph-PPV layer of about 150 nm (curve 604), with an otherwise identical device configuration. This is believed to be caused by the presence of thicker polymer making the device more resistive, and hence a higher driving voltage is expected.

A luminance of 6000 cd/m² was obtained at a voltage of 12 V for the TOLED with Ph-PPV thickness of 110 nm (curve 606) in FIG. 6b. As can be seen from FIG. 6c, the luminous efficiency varies quite substantially between different Ph-PPV thicknesses used in the respective devices. The maximum luminous efficiency of 4.6±0.1 cd/A was obtained for a TOLED with a Ph-PPV layer thickness of about 110 nm at the operating voltage of 10 V (curve 608). The luminous efficiency measured for the devices with Ph-PPV thickness of 80 nm and 150 nm is 3.4±0.1 cd/A, and 1.2±0.1 cd/A, (curves 610, 612) respectively.

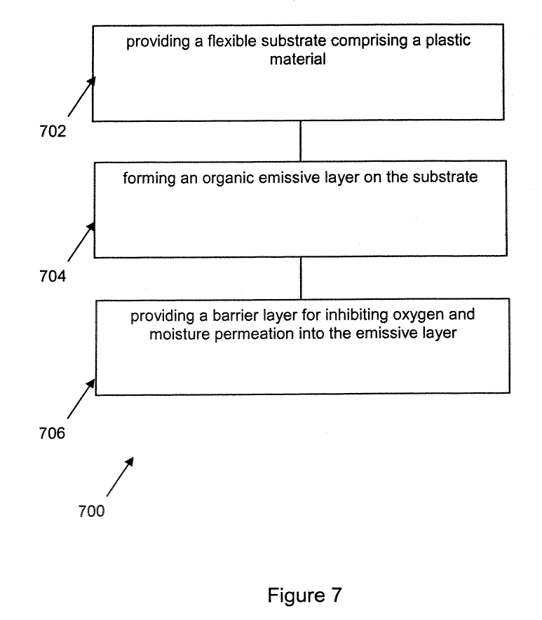

FIG. 7 shows a flow-chart 700 illustrating a method of fabricating a flexible organic light emitting device. At step 702, a flexible substrate comprising a plastic material is provided. At step 704, an organic emissive layer is formed on the substrate. At step 706, a barrier layer for inhibiting oxygen and moisture permeation into the emissive layer is provided.

Example embodiments can provide higher performance organic light-emitting diodes that exhibit high luminance and can be driven with low dc voltages. The TOLEDs with optical micro-cavity structure offer the possibility to control the spectral properties of emission.

It was found that the performance of TOLEDs according to example embodiments did not deteriorate after repeated bending.

Furthermore, the example embodiments have the potential to meet permeability standards far in excess of the most demanding display requirements of about 10⁻⁶ g/m² day, utilizing metal-plastic substrates. Furthermore, a cost-effective approach for mass production, such as roll-to-roll processing, which is a widely used industrial process, may be implemented for the metal-plastic substrate.

The example embodiments can significantly reduce the weight of flat panel displays and endow the ability to bend a display into any desired shape. For example, displays may be wrapped around the circumference of a pillar, for “foldable” and “roll-able” television sets. The example embodiments may be implemented in flexible or pre-formed curved displays and electroluminance based lighting devices.

While the present invention has been described with respect to a limited number of embodiments, those skilled in the art will appreciate numerous modifications and variations therefrom. It is intended that all such modifications and variations are covered by the spirit and scope of the appended claims.

For example, it will be appreciated that other metal-plastic substrate structures may be used in different embodiment, including a plastic layer laminated to or coated with a metal layer, or a metal film sandwiched between two plastic foils.

It will further be appreciated that the present invention is not limited to the materials and dimensions described with reference to the example embodiments. For example, the transparent conductive layer may comprise transparent conducting oxides such as indium-tin-oxide (ITO), zinc-indium-oxide, aluminum-doped zinc oxide, Ga—In—Sn—O, SnO₂, Zn—In—Sn—O, Ga—In—O, TiNbO, ZSO, NiOx or a combination of transparent conducting oxides. Also, the first electrode layer may comprise metallic or modified metallic materials such as Au, Ag/CFₓ or any transparent and opaque contact suitable for carrier injection in OLEDs.

Also, while the example embodiments described have a structure of flexible substrate/metal/anode/stack of organic layers/transparent cathode, the OLED structure can also be implemented in a configuration of flexible substrate/metal/cathode/stack of organic layers/transparent anode, in different embodiments.

1. A flexible organic light emitting device comprising:
a flexible substrate comprising a plastic material;
an organic emissive layer formed on the substrate; and
a barrier layer for inhibiting oxygen and moisture permeation into the emissive layer.

2. The device as claimed in claim 1, wherein the substrate further comprises the barrier layer.

3. The device as claimed in claim 2, wherein the substrate comprises a plastic foil laminated to or coated with the barrier layer.

4. The device as claimed in claim 3, wherein the substrate comprises the barrier layer sandwiched between two plastic foils.

5. The device as claimed in claims 3 or 4, wherein the plastic foil comprises a PET foil.

6. The device as claimed in any one of claims 3 to 5, wherein the barrier layer comprises a metallic layer.

7. The device as claimed in any one of the preceding claims, further comprising a first electrode layer.

8. The device as claimed in claim 7, wherein the first electrode layer comprises the barrier layer.

9. The device as claimed in claim 8, wherein the first electrode layer further comprises a transparent conductive layer.

10. The device as claimed in claim 9, wherein the transparent conductive layer comprises one or more transparent conducting oxides.

11. The device as claimed in any one of claims 7 to 10, wherein the first electrode layer comprises a metallic or modified metallic electrode.

12. The device as claimed in any one of the preceding claims, further comprising an optical micro-cavity including the emissive layer.

13. The device as claimed in claim 12, wherein the micro-cavity further includes a semitransparent second electrode layer formed on the organic emissive layer.

14. The device as claimed in claim 13, wherein the micro-cavity further includes the barrier layer as a reflective element on an opposite side of the emissive layer compared to the second electrode layer.

15. The device as claimed in any one of the preceding claims, wherein an optical thickness of the micro-cavity is chosen such that the device exhibits a pre-determined emission wavelength.

16. The device as claimed in any one of the preceding claims, wherein the device is incorporated in one of a group consisting of a flexible display, a pre-formed curved display, and electroluminance based lighting devices.

17. A method of fabricating a flexible organic light emitting device, the method comprising:
providing a flexible substrate comprising a plastic material;
forming an organic emissive layer on the substrate; and
providing a barrier layer for inhibiting oxygen and moisture permeation into the emissive layer.

18. The method as claimed in claim 17, further comprising forming an optical micro-cavity including the emissive layer.

19. The method as claimed in claim 18, wherein an optical thickness of the micro-cavity is chosen such that the device exhibits a pre-determined emission wavelength.
